(19) United States
(12) Patent Application Publication
(10) Pub. No.: US 2026/0371986 A1
(43) Pub. Date: Nov. 19, 2026

(54) SUBSTRATE MANUFACTURING METHOD, CHIP MANUFACTURING METHOD, AND PROCESSING APPARATUS

(71) Applicant: DISCO CORPORATION, Tokyo (JP)

(72) Inventors: Tasuku Koyanagi, Tokyo (JP); Junya Mimura, Tokyo (JP)

(21) Appl. No.: 19/566,439

(22) Filed: Mar. 13, 2026

(30) Foreign Application Priority Data
May 15, 2025 (JP) 2025-066921

(51) Int. Cl. H10P 72/00; H10P 58/00; H10P 72/70

(52) U.S. Cl. CPC H10P 72/0428; H10P 58/20; H10P 72/7442

(57) ABSTRACT

A substrate manufacturing method for obtaining a first substrate from which a second substrate has been separated, from a composite substrate having the first substrate, a temporary fixing layer, and the second substrate stacked in this order, includes applying a laser beam having a wavelength absorbable by the temporary fixing layer to the temporary fixing layer, specifying a position of a fixing force reduction region in which a fixing force between the first substrate and the second substrate in the temporary fixing layer is reduced, after the laser beam is applied to the temporary fixing layer, and separating the second substrate from the first substrate using the specified position of the fixing force reduction region.

### BACKGROUND OF THE INVENTION

### Field of the Invention

The present invention relates to a substrate manufacturing method of obtaining, from a composite substrate having a first substrate, a temporary fixing layer, and a second substrate stacked in this order, the first substrate from which the second substrate is separated, a chip manufacturing method of manufacturing a plurality of chips by dividing the first substrate after the second substrate is separated from the composite substrate, and a processing apparatus for reducing a fixing force of the temporary fixing layer in the composite layer.

### Description of the Related Art

There is known a processing process called laser lift-off (LLO) in which a laser beam is applied to a composite substrate having a first substrate and a second substrate integrated through a temporary fixing layer, to embrittle the temporary fixing layer and cause reduction in a fixing force of the temporary fixing layer before the second substrate is separated from the composite substrate (for example, see Japanese Patent Laid-Open No. 2016-21464).

In the processing process disclosed in Japanese Patent Laid-Open No. 2016-21464, when the second substrate is separated after the fixing force due to the temporary fixing layer between the first substrate and the second substrate is decreased by application of the laser beam, an external force such as ultrasonic vibration is applied to the composite substrate.

However, in LLO, to minimize damage to devices in the composite substrate as much as possible, a laser beam having an energy substantially equal to a threshold energy for destroying the temporary fixing layer may be applied to the temporary fixing layer.

Accordingly, also after the laser beam is applied, part of the temporary fixing layer may become an insufficient region in which the fixing force of the temporary fixing layer is not sufficiently reduced, and even if the external force such as ultrasonic vibration is applied to this insufficient region, separation of the second substrate may not be promoted.

In view of this, such a measure as increasing a period of time for which the external force such as ultrasonic vibration is applied to the composite substrate or increasing the external force to be applied to the composite substrate can be considered to be taken, but productivity in obtaining the first substrate from the composite substrate may be reduced due to circumstances such as a longer period of time required for separating the second substrate from the composite substrate or occurrence of breakage of the second substrate, the devices, or the like when the second substrate is separated from the composite substrate.

### SUMMARY OF THE INVENTION

Accordingly, it is an object of the present invention to enhance the productivity when the first substrate is obtained by separating the second substrate from the composite substrate.

In accordance with an aspect of the present invention, there is provided a substrate manufacturing method for obtaining, from a composite substrate in which a first substrate, a temporary fixing layer, and a second substrate are stacked in this order, the first substrate from which the second substrate has been separated. The method includes applying a laser beam having a wavelength absorbable by the temporary fixing layer, to the temporary fixing layer, after the laser beam is applied to the temporary fixing layer, specifying a position of a fixing force reduction region in which a fixing force between the first substrate and the second substrate in the temporary fixing layer is reduced, and separating the second substrate from the first substrate using the specified position of the fixing force reduction region.

In the separating of the second substrate from the first substrate, an external force may be applied to the fixing force reduction region.

In addition, in the specifying of the position of the fixing force reduction region, the position of the fixing force reduction region may be specified based on an image obtained by imaging the composite substrate.

Moreover, the substrate manufacturing method may further include, after the position of the fixing force reduction region is specified, applying the laser beam to a region of the temporary fixing layer in which the fixing force is not sufficiently reduced, to reduce the fixing force of the temporary fixing layer.

Further, the fixing force reduction region may be a region in which modification has relatively progressed in the temporary fixing layer that has been irradiated with the laser beam.

Still further, the fixing force reduction region may be a region in which the first substrate and the second substrate are spatially separated from each other or a region in which a color of an interface between the second substrate and the temporary fixing layer is changed compared to a color of the temporary fixing layer before the application of the laser beam.

In accordance with another aspect of the present invention, there is provided a chip manufacturing method of manufacturing a plurality of chips by dividing a first substrate after separating a second substrate from a composite substrate having the first substrate, a temporary fixing layer, and the second substrate stacked in this order. The method includes applying a laser beam having a wavelength absorbable by the temporary fixing layer, to the temporary fixing layer, after the laser beam is applied to the temporary fixing layer, specifying a position of a fixing force reduction region in which a fixing force between the first substrate and the second substrate in the temporary fixing layer is reduced, separating the second substrate from the first substrate, with use of the specified position of the fixing force reduction region, and after separating the second substrate from the first substrate, dividing the first substrate into the plurality of chips.

In accordance with a further aspect of the present invention, there is provided a processing apparatus for reducing a fixing force of a temporary fixing layer in a composite substrate having a first substrate, the temporary fixing layer, and a second substrate stacked in this order. The processing apparatus includes a laser beam applying unit that applies a laser beam having a wavelength absorbable by the temporary fixing layer, to the temporary fixing layer, and a fixing force reduction region specifying unit that specifies a position of a fixing force reduction region in which a fixing force between the first substrate and the second substrate is reduced in the composite substrate in which the temporary fixing layer is irradiated with the laser beam.

In the substrate manufacturing method according to the aspect of the present invention, with use of the position of the fixing force reduction region in which the fixing force between the first substrate and the second substrate, the second substrate is separated from the first substrate. As a specific example, with the specified position of the fixing force reduction region as a start point, a range to which an external force such as ultrasonic vibration is applied is moved to another region, so that the range of the fixing force reduction region is enlarged.

Accordingly, compared to a case in which the range to which the external force is applied with the specified position of the fixing force reduction region as a start point is not moved to another region (for example, a case in which an external force such as ultrasonic vibration is applied only to an insufficient region to which the fixing force of the fixing layer is not sufficiently reduced), it is possible to enlarge the range of the fixing force reduction region easily.

Specifically, compared to a case in which such a measure as increasing a period of time for applying an external force such as ultrasonic vibration to the insufficient region to which the fixing force of the temporary fixing layer is not sufficiently reduced or further increasing the external force to be applied is taken without taking a measure of specifying the position of the fixing force reduction region, the range of the fixing force reduction region can be efficiently increased, so that reduction in productivity in obtaining the first substrate from the composite substrate can be prevented.

In the chip manufacturing method according to the other aspect of the present invention, the second substrate is separated from the first substrate as in the substrate manufacturing method described above, so that reduction in productivity in obtaining the first substrate from the composite substrate can be prevented. Hence, reduction in productivity of chips can be prevented.

In the processing apparatus according to the further aspect of the present invention, the fixing force reduction region specifying unit specifies the position of the fixing force reduction region. Then, with the specified position of the fixing force reduction region as a start point, an external force such as ultrasonic vibration is also applied to another region, and accordingly, the range of the fixing force reduction region can be enlarged relatively easily, so that reduction in productivity in obtaining the first substrate from the composite substrate can be prevented.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is an exploded perspective view illustrating a composite substrate;

FIG. 1B is a cross-sectional view illustrating the composite substrate;

FIG. 2 is a view illustrating a thinning step of thinning a support substrate;

FIG. 3 is a flowchart illustrating a manufacturing method of device chips according to a first embodiment;

FIG. 4 is a perspective view illustrating a laser processing apparatus;

FIG. 5 is a view illustrating a fixing force reduction step in the manufacturing method of device chips according to the first embodiment;

FIG. 6 is a view illustrating a specifying step of specifying a position of a fixing force reduction region in the manufacturing method of device chips according to the first embodiment;

FIG. 7 is a schematic view illustrating the whole composite substrate as viewed in an XY plane;

FIG. 8 is a grayscale image of the composite substrate having the fixing force reduction region as viewed in the XY plane;

FIG. 9 is a binary image obtained by performing binary processing on the image depicted in FIG. 8;

FIG. 10 is a view illustrating an external force application step in a separation step in the manufacturing method of device chips according to the first embodiment;

FIG. 11 is a view illustrating a peel-off step in the separation step in FIG. 10;

FIG. 12A is a view illustrating a dividing step in the manufacturing method of device chips according to the first embodiment;

FIG. 12B is a perspective view illustrating one device chip;

FIG. 13 is a view illustrating a modification example of the dividing step in FIG. 12A;

FIG. 14 is a flowchart illustrating a manufacturing method of device chips according to a second embodiment;

FIG. 15A is a view illustrating a composite substrate formation step in the manufacturing method of device chips according to the second embodiment;

FIG. 15B is a cross-sectional view illustrating the composite substrate;

FIG. 16 is a view illustrating a fixing force reduction step in the manufacturing method of device chips according to the second embodiment;

FIG. 17 is a view illustrating a specifying step in the manufacturing method of device chips according to the second embodiment;

FIG. 18 is a view illustrating an external force application step in a separation step in the manufacturing method of device chips according to the second embodiment; and

FIG. 19 is a view illustrating a peel-off step in the separation step in FIG. 18.

### DETAILED DESCRIPTION OF THE PREFERRED EMBODIMENTS

### First Embodiment

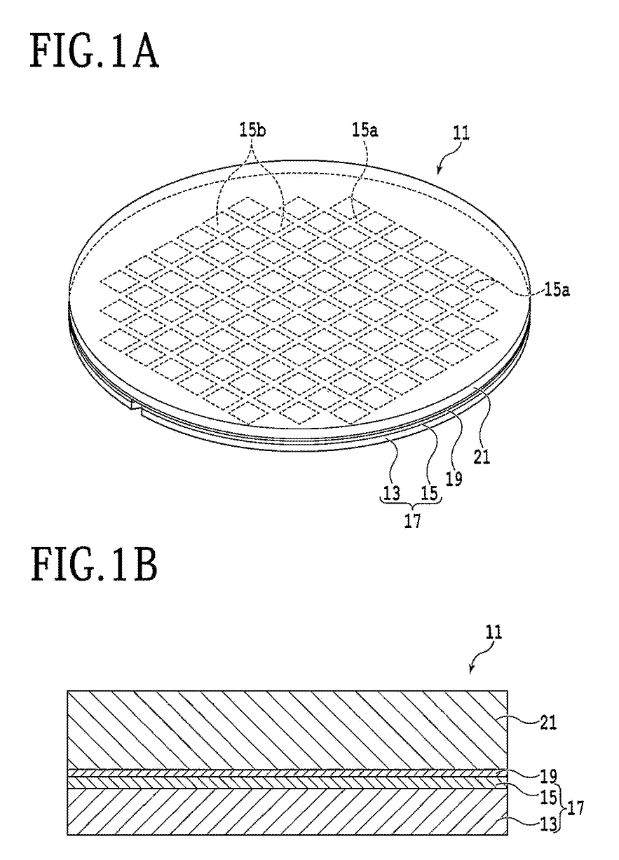

An embodiment according to one mode of the present invention will be described with reference to the attached drawings. FIG. 1A is an exploded perspective view illustrating a composite substrate 11, and FIG. 1B is a cross-sectional view illustrating the composite substrate 11. The composite substrate 11 has a support substrate (i.e., a first substrate) 13, a device layer 15, a temporary fixing layer 19, and a base substrate (i.e., a second substrate) 21 stacked on top of one another in this order.

However, as long as this order is kept and the manufacturing method described below can be performed, the composite substrate 11 may further include another layer. By way of example, the composite substrate 11 can include a layer having a structure or a material different from those of the support substrate 13 and the device layer 15 between the support substrate 13 and the device layer 15.

The support substrate 13 according to the present embodiment is disc-shaped and formed of sapphire, silicon carbide, or the like. A diameter of the support substrate 13 is 10 to 300 mm (typically, 50 mm), for example, and the thickness of the support substrate 13 is 100 to 3000 µm (typically, 600 µm), for example.

A fixing layer (not illustrated) is provided on a front surface of the support substrate 13 so as to cover the entire region thereof. The fixing layer is formed of a gold-tin alloy, gold, platinum, chromium, indium, or palladium, for example. The device layer 15 is provided in contact with the fixing layer on a side of the fixing layer opposite to the support substrate 13.

The device layer 15 includes an n-type gallium nitride semiconductor film and a p-type gallium nitride semiconductor film stacked on top of one another, for example. These semiconductor films constituting the device layer 15 are in contact with the temporary fixing layer 19, which is to be described later, functioning as a buffer layer and are formed by epitaxial growth.

The thickness of the device layer 15 is 3 to 50 µm (typically, 10 µm), for example. Note that, in the present embodiment, a stacked body including the support substrate 13, the fixing layer, the device layer 15, and the like is referred to as a device substrate 17.

A plurality of dividing lines 15a each extending linearly are set in a grid manner on one surface of the device layer 15 (for example, one surface being in contact with the temporary fixing layer 19). Each of rectangular regions demarcated by the plurality of dividing lines 15a has a device 15b provided therein.

The device 15b is not limited to any particular kind. For example, while the device 15b is an optical device such as a light emitting diode (LED) or a laser diode (LD), the device 15b may instead be a power device such as an insulated gate bipolar transistor (IGBT) or a high electron mobility transistor (HEMT), or an integrated circuit (IC).

The base substrate 21 is disc-shaped having a diameter substantially the same as that of the support substrate 13 and is formed of sapphire that transmits visible light, silicon carbide, or the like. However, the base substrate 21 is not limited to the materials described above, and may be formed of a semiconductor material such as single-crystal silicon (Si) that transmits infrared light. The thickness of the base substrate 21 is 0.5 to 3 mm (typically, 1 mm), for example.

A front surface of the base substrate 21 is exposed as an external surface of the composite substrate 11. A back surface of the base substrate 21 has the temporary fixing layer 19 provided thereon, the temporary fixing layer 19 functioning as a buffer layer between the base substrate 21 and the device layer 15. The temporary fixing layer 19 is formed of gallium nitride (GaN), for example. The thickness of the buffer layer is 0.2 to 5 µm (typically, 1 µm), for example.

When the composite substrate 11 is to be formed, first, the temporary fixing layer 19 and the device layer 15 are sequentially formed on the base substrate 21. Then, after a metal fixing layer (not illustrated) is formed on the front surface of the support substrate 13 by deposition, the fixing layer formed on the support substrate 13 and the device layer 15 formed over the base substrate 21 are pressed against each other, in a state of being brought in contact with each other. Accordingly, the composite substrate 11 is formed. Note that, upon press bonding, one of or both the support substrate 13 and the base substrate 21 may be heated.

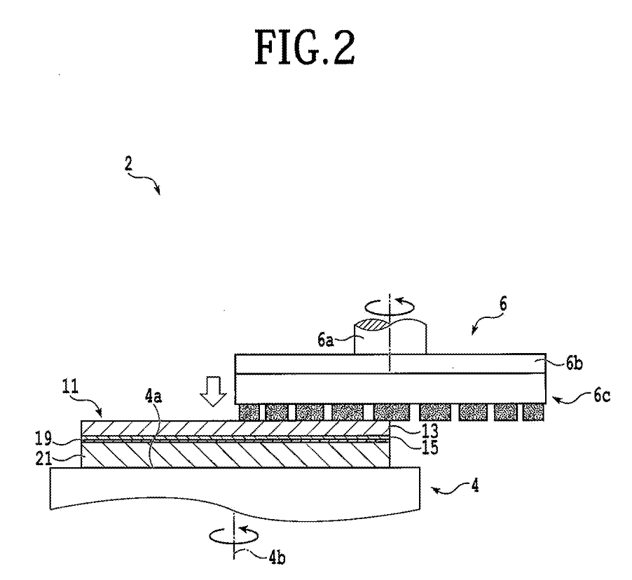

According to the present embodiment, the support substrate 13 of the composite substrate 11 is ground and thinned. FIG. 2 is a view illustrating a thinning step of thinning the support substrate 13 with use of a grinding apparatus 2. When the support substrate 13 is to be ground, first, the composite substrate 11 is held under suction on a holding surface 4a of a chuck table 4 in such a manner that the support substrate 13 is exposed upward.

Next, while the chuck table 4 is rotated about a rotational axis 4b and a spindle 6a, a mount 6b, and a grinding wheel 6c are rotated in an integrated manner, a grinding unit 6 is moved downward at a predetermined grinding speed.

As for infeed grinding illustrated in FIG. 2, the support substrate 13 is ground along an arcuate portion of a circular path on the holding surface 4a, among circular paths of a plurality of grindstones generated at rotation of the spindle 6a, and owing to rotation of the chuck table 4, the entire exposed surface of the support substrate 13 is uniformly ground, so that the support substrate 13 is uniformly thinned. Note that grinding of the support substrate 13 may not be required and may be omitted.

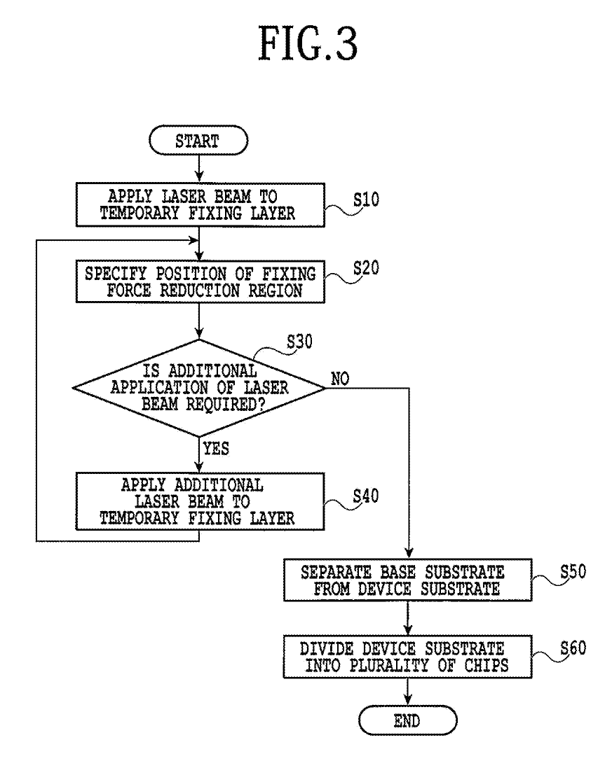

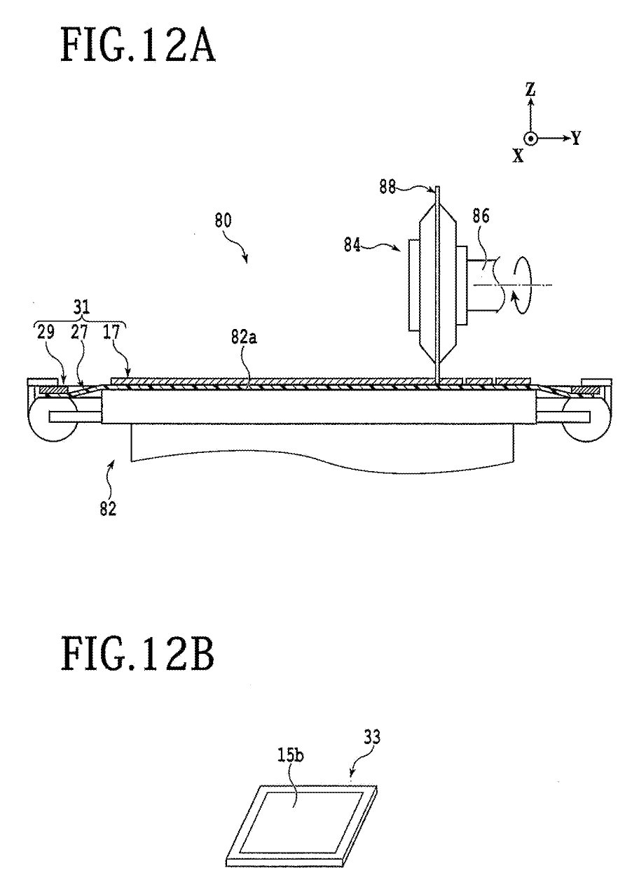

Then, with reference to FIGS. 3-12B , a method of manufacturing device chips 33 in which, after the base substrate 21 is separated from the composite substrate 11, the device substrate 17 including the support substrate 13, the device layer 15, and the like is divided into individual devices 15b, resulting in manufacture of a plurality of device chips (i.e., chips) 33 (see FIG. 12B), will be described.

FIG. 3 is a flowchart illustrating a manufacturing method of the device chips 33 according to the present embodiment. Note that the manufacturing method of the device chips 33 includes a substrate manufacturing method of separating the base substrate 21 from the composite substrate 11 to obtain the device substrate 17 (i.e., S10 to S50).

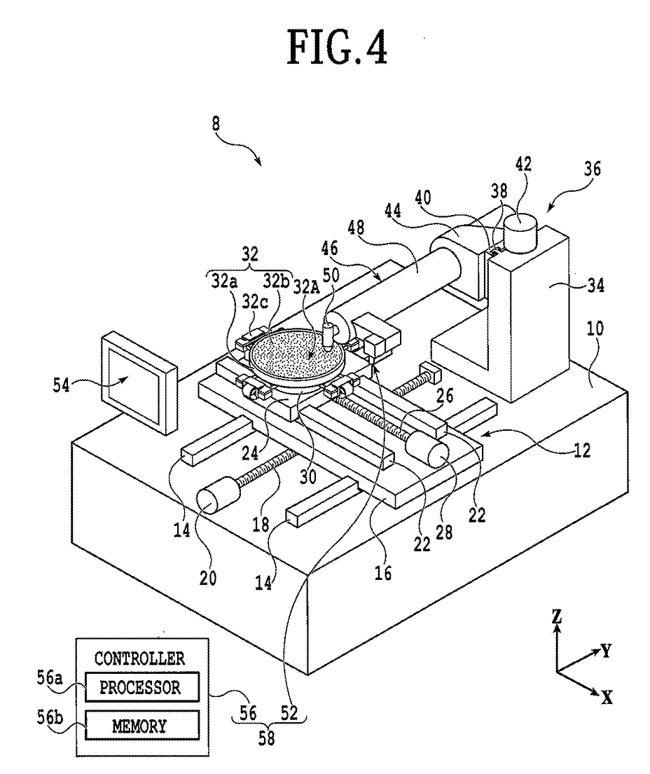

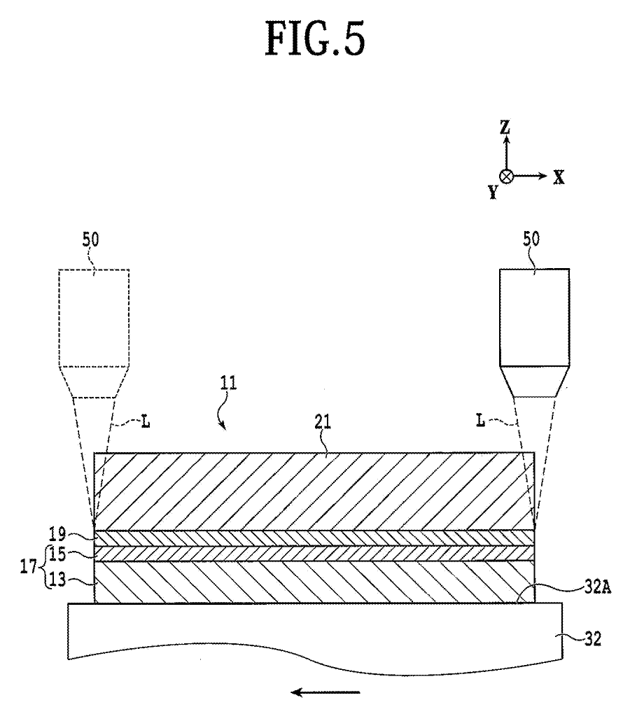

First, with reference to FIG. 4, a laser processing apparatus (that is, a processing apparatus) 8 to be used for applying a laser beam L (see FIG. 5) to the temporary fixing layer 19 will be described. FIG. 4 is a perspective view illustrating the laser processing apparatus 8.

An X-axis direction, a Y-axis direction, and a Z-axis direction illustrated in FIG. 4 extend perpendicularly to one another. The X-axis direction is parallel to a processing feed direction in the processing apparatus 8, and the Y-axis direction is parallel to an index feed direction in the processing apparatus 8.

In addition, a plane defined by the X-axis direction and the Y-axis direction is parallel to a horizontal plane, for example, and the Z-axis direction is parallel to a vertical direction. Note that, in FIG. 4, some of components are illustrated as functional blocks. The laser processing apparatus 8 has a base 10 supporting the components.

A horizontal moving mechanism 12 is provided on an upper surface of the base 10. The horizontal moving mechanism 12 is fixed to the upper surface of the base 10, and has a pair of guide rails 14 each longitudinal portion of which is provided along the Y-axis direction.

In addition, on an upper surface side of the pair of guide rails 14, there is provided a Y-axis direction moving plate 16 slidably attached to the pair of guide rails 14. On a lower surface side of the Y-axis direction moving plate 16, there is provided a nut portion (not illustrated).

A screw shaft 18 having a longitudinal portion provided along the Y-axis direction is provided between the pair of guide rails 14. The screw shaft 18 is rotatably coupled to the nut portion through a plurality of balls (not illustrated). The screw shaft 18 has one end coupled to a drive source 20 such as a servomotor.

When the drive source 20 is actuated, the screw shaft 18 is rotated, and the Y-axis direction moving plate 16 moves along the Y-axis direction. The pair of guide rails 14, the Y-axis direction moving plate 16, the screw shaft 18, the drive source 20, and the like constitute a Y-axis direction moving mechanism.

A pair of guide rails 22 each longitudinal portion of which is provided along the X-axis direction are provided on an upper surface of the Y-axis direction moving plate 16. An X-axis direction moving plate 24 slidably attached to the pair of guide rails 22 is provided on the upper surface of the pair of guide rails 22.

A nut portion (not illustrated) is provided on a lower surface of the X-axis direction moving plate 24. A screw shaft 26 having a longitudinal portion provided along the X-axis direction is provided between the pair of guide rails 22. The screw shaft 26 is rotatably coupled to the nut portion through a plurality of balls (not illustrated).

The screw shaft 18 has one end coupled to a drive source 28 such as a servomotor. When the drive source 28 is actuated, the screw shaft 26 is rotated, and the X-axis direction moving plate 24 moves along the X-axis direction. The pair of guide rails 22, the X-axis direction moving plate 24, the screw shaft 26, the drive source 28, and the like constitute an X-axis direction moving mechanism.

A cylindrical portion 30 is provided on an upper surface of the X-axis direction moving plate 24, and a disc-shaped chuck table (that is, a holding table) 32 for holding under suction the composite substrate 11 is provided at a top portion of the cylindrical portion 30. In the cylindrical portion 30, a rotational driving mechanism (not illustrated) having a motor is provided.

When the rotational driving mechanism is actuated, the chuck table 32 is rotated about a rotational axis substantially parallel to the Z-axis direction. The chuck table 32 has a disc-shaped frame body 32a made of metal such as stainless steel.

At a radially central portion of the frame body 32a, a disc-shaped recessed portion is provided concentrically. A disc-shaped porous plate 32b made of porous ceramic is fixed to the recessed portion of the frame body 32a. An outer diameter of the porous plate 32b is substantially the same as an inner diameter of the recessed portion of the frame body 32a.

A suction source (not illustrated) such as a vacuum pump or an ejector is connected to the frame body 32a. A negative pressure generated by the suction source is transmitted to an upper surface of the porous plate 32b through the frame body 32a. Upper surfaces of the frame body 32a and the porous plate 32b are substantially flush with each other and function as a holding surface 32A for holding under suction the composite substrate 11.

Outside the chuck table 32 in a radial direction of the chuck table 32, there are provided a plurality of (four, in the present embodiment) clamp mechanisms 32c in such a manner as to protrude outward from an outer peripheral portion of the frame body 32a. The plurality of clamp mechanisms 32c are disposed at substantially equal intervals in the circumferential direction of the chuck table 32.

Each of the clamp mechanisms 32c clamps a frame included in a composite substrate unit having the composite substrate 11, a tape, and the frame (none of which are illustrated) integrated, in the Z-axis direction, to be fixed thereto.

Note that the frame is made of metal such as stainless steel and has a circular shape including an opening with a diameter larger than that of the composite substrate 11. The opening of the frame has a circular resin tape attached thereto in such a manner as to close the opening, and the composite substrate 11 is supported by the frame through the tape.

In the composite substrate unit according to the present embodiment, since the support substrate 13 is in contact with the tape, the base substrate 21 is exposed upward (see FIG. 5). The composite substrate 11 is automatically transferred to the chuck table 32 in the form of the composite substrate unit and thereafter processed.

However, in a case in which an operator manually transfers the composite substrate 11 to the chuck table 32, the tape and the frame are omitted, and the composite substrate 11 itself may be placed on the holding surface 32A of the chuck table 32. In this case, the support substrate 13 is in contact with the holding surface 32A.

Note that, in place of the chuck table 32, an electrostatic chuck (not illustrated) may be used to hold under suction the composite substrate 11 on a holding surface of the electrostatic chuck due to an electrostatic force. In addition, in place of the chuck table 32, it is also possible to use an unillustrated composite substrate fixing table having a disc-shaped plate with a substantially flat upper surface and a plurality of clamp mechanisms provided discretely at an outer peripheral portion of the disc-shaped plate to physically fix an outer peripheral portion of the composite substrate 11.

There is provided a support structure 34 in the vicinity of the horizontal moving mechanism 12 and on the upper surface of the base 10. On one side surface of the support structure 34, a Z-axis direction moving mechanism 36 is provided. The Z-axis direction moving mechanism 36 has a pair of guide rails 38 fixed on the one side surface of the support structure 34.

A longitudinal portion of each of the guide rails 38 is disposed along the Z-axis direction. Note that, in FIG. 4, only one of the guide rails 38 is illustrated. To the pair of guide rails 38, a Z-axis direction moving plate 40 is slidably fixed. The Z-axis direction moving plate 40 has a back surface with a nut portion (not illustrated) provided thereon.

A screw shaft (not illustrated) having a longitudinal portion disposed along the Z-axis direction is provided between the pair of guide rails 38. This screw shaft is coupled to the nut portion in a rotatable manner through a plurality of balls (not illustrated).

A drive source 42 such as a servomotor is coupled to an upper end of the screw shaft. When the drive source 42 is actuated, the Z-axis direction moving plate 40 moves along the Z-axis direction. A support member 44 is fixed to a front surface of the Z-axis direction moving plate 40.

The support member 44 supports a cylindrical housing 48 that is one of components of a laser beam applying unit 46. The laser beam applying unit 46 includes a laser oscillator (for example, excimer laser) (not illustrated) fixed to the base 10.

The laser oscillator emits a laser beam having a wavelength (for example, 193 or 248 nm) absorbable by the temporary fixing layer 19 and transmissible through the base substrate 21. While the laser beam according to the present embodiment is a pulsed wave (for example, with a repetitive frequency of 50 Hz and a pulse width of 10 ns), the laser beam may instead be a continuous wave.

The laser beam emitted from the laser oscillator passes through an attenuator, a liquid crystal on silicon spatial light modulator (LCOS-SLM), a beam shaper, or the like as appropriate, and is guided to a head portion 50, according to the required specifications.

The housing 48 has the head portion 50 provided at a distal end portion thereof. The head portion 50 houses a mirror, a focusing lens, and the like (none of which are illustrated). The head portion 50 emits a laser beam L toward the holding surface 32A of the chuck table 32 in such a manner that the laser beams L is focused at a predetermined height position in the Z-axis direction by the focusing lens.

As described later, the laser beam L is applied to the temporary fixing layer 19 through the base substrate 21. The temporary fixing layer 19 absorbs an energy of the laser beam L to be heated and decomposed. This results in reduction in a fixing force of the temporary fixing layer 19 to the device layer 15 and/or the base substrate 21.

In the present embodiment, the chuck table 32 is moved in the X-axis direction and the Y-axis direction relative to a focusing spot of the laser beam L applied from the head portion 50, so that the laser beam L is applied to the substantially entire surface of the temporary fixing layer 19. Alternatively, the head portion 50 may adopt a galvanoscanner, and in a state in which the chuck table 32 is kept stational, the focusing spot of the laser beam L may be moved relative to the temporary fixing layer 19.

Meanwhile, the housing 48 has a microscope camera unit 52 provided at a side portion of the distal end portion of the housing 48. The microscope camera unit 52 is used when the temporary fixing layer 19 of the composite substrate 11 after the laser beam L is applied to the temporary fixing layer 19 is imaged, for example.

The microscope camera unit 52 includes a light source such as an LED, an objective lens, and a camera unit. The camera unit includes not only a lens, an aperture, and the like, but also a solid-state imaging element such as a complementary metal oxide semiconductor (CMOS) image sensor.

In the present embodiment, since the temporary fixing layer 19 is imaged with use of visible light, an LED that emits visible light transmissible through the base substrate 21 is used as the light source, and an image sensor that has a photodiode capable of converting the visible light into charge by photoelectric conversion is used as the solid-state imaging element.

Note that, in a case in which the base substrate 21 does not allow visible light to pass therethrough but allows infrared light to pass therethrough, an LED that emits infrared light is used as the light source in order to image the temporary fixing layer 19 with use of the infrared light, and an image sensor having a photodiode capable of performing photoconversion on the infrared light is used as the solid-state imaging element.

Note that, in the present embodiment, a two-dimensional area sensor is used as an image sensor, and a line sensor may be used instead. In addition, in place of such light as the visible light or the infrared light, a reflected wave of an ultrasonic wave may be used to visualize an internal structure of the composite substrate 11, and accordingly, the temporary fixing layer 19 may be imaged.

Upon imaging of the temporary fixing layer 19 with use of an ultrasonic wave, a single probe including one ultrasonic transducer that receives a reflected wave after an ultrasonic wave is generated from the one ultrasonic transducer may be adopted, or an array probe including a plurality of ultrasonic transducers each of which can generate an ultrasonic wave and receive a reflected wave may be adopted.

An image obtained by imaging is subjected to image processing by a controller 56 to be described later. The controller 56 specifies a position of a fixing force reduction region 19A in which the fixing force between the device substrate 17 and the base substrate 21 of the composite substrate 11 is reduced, based on the processed image. In this manner, the microscope camera unit 52 and the controller 56 function as a fixing force reduction region specifying unit 58.

A side portion and a top portion of the base 10 are covered with a cover (not illustrated). This cover has a touch panel display 54 provided on one surface thereof. The touch panel display 54 functions as an input unit by which an operator inputs an instruction to the laser processing apparatus 8 and a display unit that displays an image or the like which is obtained by the microscope camera unit 52.

Note that, in place of the touch panel display 54, a display unit that does not have a function of the input unit may be provided in the laser processing apparatus 8. In this case, however, the input unit (a keyboard, a mouse, a trackball, a touch pad, digitizer, or the like) for the operator inputting an instruction to the laser processing apparatus 8 is separately provided.

The horizontal moving mechanism 12, the rotational driving mechanism, the chuck table 32, the Z-axis direction moving mechanism 36, the laser beam applying unit 46, the microscope camera unit 52, the touch panel display 54, and the like are controlled in operation by the controller 56.

The controller 56 includes a computer having a processor 56a as exemplified by a central processing unit (CPU) and a memory 56b, for example. The memory 56b includes a main storage unit such as a dynamic random access memory (DRAM), and an auxiliary storage unit such as a flash memory, a hard disk drive (HDD), and a solid state drive (SSD).

The auxiliary storage unit stores software including a predetermined program. When the processor 56a and the like are operated according to this software, the function of the controller 56 is implemented.

The predetermined program executed by the processor 56a may be stored in a non-transitory tangible recording medium such as a universal serial bus (USB) memory, an optical disc, a secure digital (SD) memory card, or an HDD, in place of the auxiliary storage device.

As a program to be stored in the memory 56b, for example, there is a program for performing a fixing force reduction step S10 and a specifying step S20 of specifying the fixing force reduction region 19A. In addition, as data to be stored in the memory 56b, there are data regarding processing conditions when performing the fixing force reduction step S10 and image data obtained in the specifying step S20, for example.

FIG. 5 is a view illustrating the fixing force reduction step S10 of reducing the fixing force between the device layer 15 and the base substrate 21 as a result of application of the laser beam L to the temporary fixing layer 19. In the fixing force reduction step S10, first, in such a manner that the front surface of the base substrate 21 is exposed upward, the composite substrate 11 is held under suction on the holding surface 32A of the chuck table 32 through the tape, and the frame is clamped with the clamp mechanisms 32c.

Then, in such a manner that the chuck table 32 is moved until part of a region at the outer peripheral portion of the composite substrate 11 comes to a position adjacent to the head portion 50 in the X-axis direction as viewed in the XY plane, the controller 56 controls the horizontal moving mechanism 12.

In addition, the controller 56 controls the Z-axis direction moving mechanism 36 in such a manner that the head portion 50 is moved in the Z-axis direction until the focusing spot of the laser beam L is positioned at a height corresponding to the height of the temporary fixing layer 19 in the composite substrate 11.

Subsequently, while the head portion 50 is applying the laser beams L, the controller 56 controls the laser beam applying unit 46 and the horizontal moving mechanism 12 in such a manner that the focusing spot of the laser beam L moves across the composite substrate 11 along the X-axis direction from one end to the other end thereof. The processing conditions when the focusing spot of the laser beam L is scanned within the temporary fixing layer 19 in this manner are as follows, for example.
Average power: 0.044 to 0.08 W
Area of focusing spot: 400 µm²
Relative moving speed of focusing spot: 20 mm/s

Then, in such a manner that the laser beam L moves across unirradiated regions of the temporary fixing layer 19 in the X-axis direction, the controller 56 controls the horizontal moving mechanism 12 to index feed the chuck table 32 in the Y-axis direction by a predetermined distance.

Then, while the laser beam L is applied from the head portion 50, the controller 56 controls the laser beam applying unit 46 and the horizontal moving mechanism 12 such that the scanning direction of the laser beam L is opposite to the first scanning direction. Hence, the focusing spot of the laser beam L moves across the composite substrate 11 along the X-axis direction from one end to the other end thereof.

Subsequently, the chuck table 32 is again index fed by a predetermined distance in the Y-axis direction. In this manner, scanning of the laser beam L along the X-axis direction and index-feeding of the chuck table 32 along the Y-axis direction are successively repeated, and the laser beam L is applied to substantially the whole of the temporary fixing layer 19.

Note that, in the fixing force reduction step S10, scanning of the laser beam L relative to the composite substrate 11 may be performed in both directions parallel to the X-axis direction as viewed in the XY plane or may be performed only in one direction of them.

In addition, in the fixing force reduction step S10, scanning of the laser beam L relative to the composite substrate 11 may be performed in a non-linear manner as viewed in the XY plane. For example, in such a manner that the path of the focusing spot of the laser beam L in the composite substrate 11 is in a spiral, concentric, zigzag, or radial form, the focusing spot and the composite substrate 11 may be moved relative to each other.

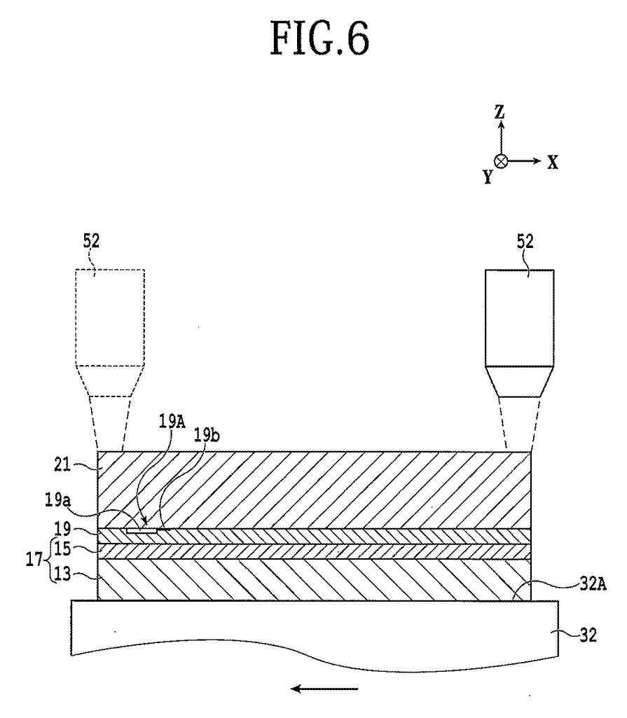

In the fixing force reduction step S10, at least a portion of the temporary fixing layer 19 absorbs the energy of the laser beam L to be heated and decomposed and becomes a region in which the base substrate 21 and the device substrate 17 are spatially separated from each other (that is, a gap 19a (see FIG. 6)).

In addition, other portions of the temporary fixing layer 19 absorb the energy of the laser beam L and become brittle, but the base substrate 21 and the temporary fixing layer 19 may not be spatially separated from each other.

More specifically, the other portions of the temporary fixing layer 19 may not be spatially separated from the base substrate 21, but when visualization is made with the microscope camera unit 52, the other portions of the temporary fixing layer 19 may become a region (that is, a modified region 19b (see FIG. 6)) in which the color of the interface between the base substrate 21 and the temporary fixing layer 19 may change compared to the color of the temporary fixing layer 19 before the application of the laser beam L.

Note that, in the present embodiment, among the gap 19a and the modified region 19b, a region formed in the temporary fixing layer 19 owing to the application of the laser beam L is referred to as the fixing force reduction region 19A. The fixing force reduction region 19A may have the gap 19a only, the modified region 19b only, or both of them.

In other words, the fixing force reduction region 19A is a region in which modification has relatively progressed in the temporary fixing layer 19 that has been irradiated with the laser beam L. According to the image obtained by the microscope camera unit 52 imaging the temporary fixing layer 19, the gap 19a and the modified region 19b can be detected in a manner being capable of distinguishing them.

The region of the temporary fixing layer 19 excluding the fixing force reduction region 19A does not have separation or modification for some reason, although the laser beam L has been applied thereto, and it becomes a region in which the fixing force between the base substrate 21 and the device substrate 17 is not sufficiently reduced but is maintained (that is, an insufficient region described above).

Meanwhile, in the fixing force reduction step S10 of the present embodiment, in order to reduce damage to the devices 15b in the composite substrate 11 as much as possible, the laser beam L having energy substantially equal to the threshold of energy capable of destroying the temporary fixing layer 19 is applied to the temporary fixing layer 19.

Hence, even after the application of the laser beam L, most of the portions of the temporary fixing layer 19 (for example, a half or more of the whole area thereof) become the insufficient region in which the fixing force of the temporary fixing layer 19 is not sufficiently reduced (that is, a region is neither the gap 19a nor the modified region, but a region in which the fixing force is relatively higher).

In this case, in order to separate the base substrate 21 by the external force such as ultrasonic vibration being applied, as a period of time for applying the external force such as ultrasonic vibration to the insufficient region of the temporary fixing layer 19 is made longer, a period of time required for separating the base substrate 21 increases accordingly.

In addition, increasing the external force such as ultrasonic vibration to be applied to the insufficient region of the temporary fixing layer 19 may cause breakage of the base substrate 21, the devices 15b, and the like when the base substrate 21 is separated. In view of this, in the present embodiment, the position of the fixing force reduction region 19A is first specified, and a region to be applied with the external force with the position of the fixing force reduction region 19A as a start point is moved.

FIG. 6 is a view illustrating the specifying step S20 of specifying the position of the fixing force reduction region 19A in which the fixing force between the device substrate 17 and the base substrate 21 is reduced, after the laser beam L is applied to substantially the whole of the temporary fixing layer 19.

In the specifying step S20, first, the microscope camera unit 52 images a predetermined rectangular range of the composite substrate 11 as viewed in the XY plane. Imaging with the microscope camera unit 52 and moving of the imaged region with the horizontal moving mechanism 12 are repeated. Accordingly, substantially the whole of the composite substrate 11 (that is, substantially the whole of the temporary fixing layer 19) as viewed in the XY plane is imaged.

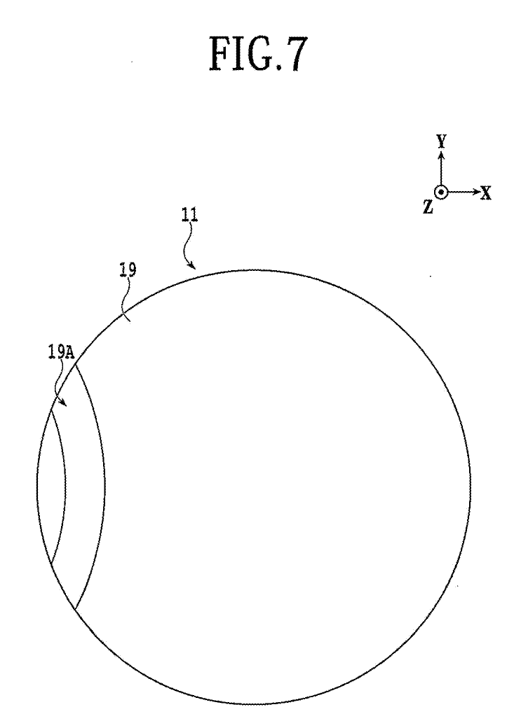

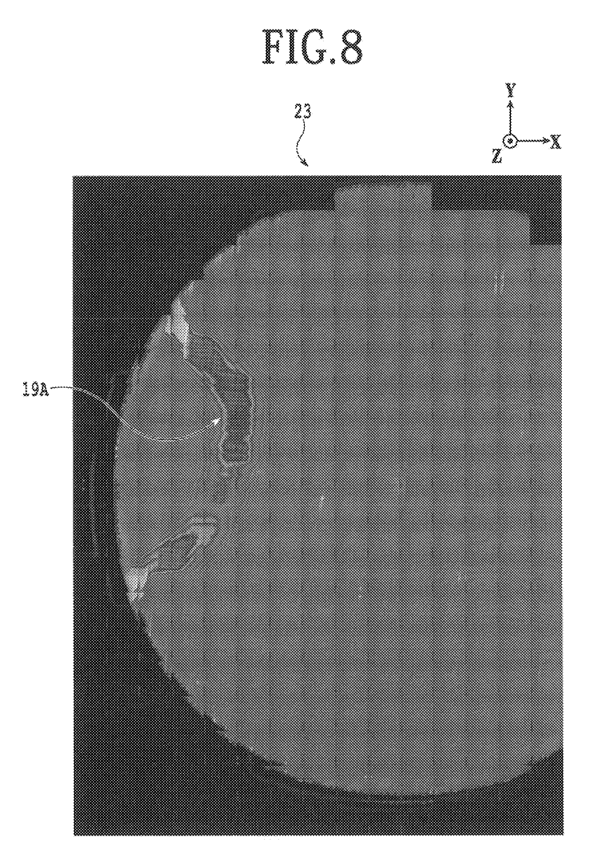

FIG. 7 is a schematic view illustrating the whole composite substrate 11 as viewed in the XY plane, and FIG. 8 is a grayscale image 23 of the composite substrate 11 having the fixing force reduction region 19A in the YX plan view. In an example illustrated in FIG. 8, the composite substrate 11 is imaged with the visible light through the base substrate 21, and an image of substantially the whole of the temporary fixing layer 19 is obtained.

In the present embodiment, the controller 56 creates the grayscale image 23 of the entire temporary fixing layer 19 by patching together some ranges of the temporary fixing layer 19, each of the ranges having a rectangular shape. Alternatively, with a camera capable of imaging a wider area than the microscope camera unit 52, the entire temporary fixing layer 19 as viewed in the XY plane may be imaged to obtain the grayscale image 23 of the entire temporary fixing layer 19. Note that the controller 56 may obtain a color image of the temporary fixing layer 19.

After the controller 56 of the present embodiment obtains the grayscale image 23 of the entire temporary fixing layer 19, binarization processing is performed on the grayscale image 23, and the position and the range of the fixing force reduction region 19A are further specified. Specifically, based on the image obtained by imaging the composite substrate 11 as viewed in the XY plane, the position and the range of the fixing force reduction region 19A are specified.

While the position and the range of the fixing force reduction region 19A are specified based on XY coordinates where the center of the radial direction of the holding surface 32A of the chuck table 32 is set as an origin, the position of the origin may not be limited to a particular position.

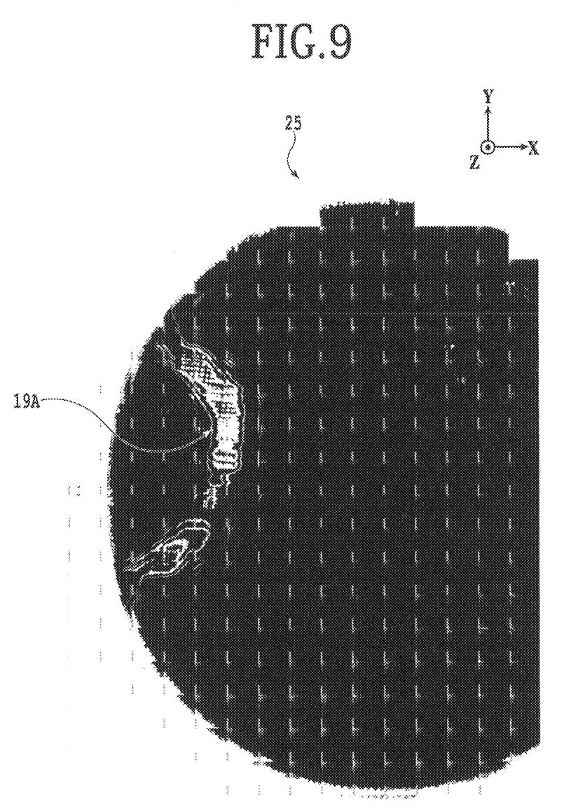

FIG. 9 is a binary image 25 obtained by performing the binary processing on the grayscale image 23 illustrated in FIG. 8. In the binary image 25 illustrated in FIG. 9, the fixing force reduction region 19A is illustrated in white, and the insufficient region in which the fixing force is not sufficiently reduced is illustrated in black.

Note that a white line segment cyclically generated in the Y-axis direction in the binary image 25 of FIG. 9 is a boundary of a range obtained by one round of imaging with the microscope camera unit 52 and is not the fixing force reduction region 19A.

Meanwhile, for example, as for reflectance with respect to the visible light, reflectance of the gap 19a is higher than that of the modified region 19b, and accordingly, the gap 19a is brighter than the modified region 19b in the grayscale image 23.

Hence, based on the difference in brightness in the grayscale image 23, the controller 56 may specify the position and the range of the gap 19a and then specify the position and the range of the modified region 19b.

Meanwhile, the position and the range of the fixing force reduction region 19A can also be specified not by the image but by measuring the thickness of the composite substrate 11.

More specifically, in the region in which the fixing force reduction region 19A is formed, a stress between the base substrate 21 and the device substrate 17 is released, and the thickness of the composite substrate 11 tends to increase locally. In view of this, the thickness of the composite substrate 11 is measured from a side surface of the composite substrate 11, and a region in which the thickness of the composite substrate 11 increases more than that before the laser beam L is applied to the temporary fixing layer 19 is specified.

More specifically, the thicknesses of regions that are different from one another in a circumferential direction of the composite substrate 11 are successively measured. For example, the thickness of the outer peripheral portion of the composite substrate 11 is measured over the entire circumference of the composite substrate 11. Upon measurement of the thickness, an operator may measure the thickness of the composite substrate 11 with calipers, and the thickness of the composite substrate 11 may be measured by use of an image obtained by imaging the composite substrate 11 with a camera that is disposed in such a manner as to view the composite substrate 11 from the side thereof.

Accordingly, the position of the fixing force reduction region 19A that reaches the outer peripheral edge of the composite substrate 11 can be specified. Note that, instead of side view, with a distance measurement sensor that measures the distance to the composite substrate 11 in a state in which the composite substrate 11 is viewed in plan, irregularities generated in the base substrate 21 are measured, and accordingly, the position and the range of the fixing force reduction region 19A may be specified.

After the specifying step S20, the controller 56 determines whether or not additional application of the laser beam L to the temporary fixing layer 19 is required (determination step S30). For example, in a case in which there is no fixing force reduction region 19A in the binary image 25 or the fixing force reduction region 19A in the binary image 25 is extremely small (that is, YES in S30), the laser beam L is additionally applied to the temporary fixing layer 19 (additional beam application step S40).

In the additional beam application step S40, the region of the temporary fixing layer 19 in which the fixing force is not sufficiently reduced is irradiated with the laser beam L, and the fixing force of the temporary fixing layer 19 is reduced.

In the additional beam application step S40, for example, in a case in which the controller 56 determines that there is no fixing force reduction region 19A in the binary image 25, the laser beam L is applied to substantially the whole of the temporary fixing layer 19.

In addition, in a case in which the controller 56 determines that the fixing force reduction region 19A is formed in a significantly reduced area, the laser beam L is applied only to the periphery of the relevant fixing force reduction region 19A, and accordingly, the relevant fixing force reduction region 19A may be increased. According to the present embodiment, after the additional beam application step S40, the process flow returns to the specifying step S20.

However, in the specifying step S20 before the additional beam application step S40, in a case in which the position at which the fixing force reduction region 19A having a extremely small area has already been formed can be specified, it is considered that the area of the fixing force reduction region 19A that has already been formed is enlarged after the additional beam application step S40, the process flow does not return to the specification step S20 after the additional beam application step S40 and may advance to the separation step S50.

As a matter of course, the additional beam application step S40 may be performed in multiple times, and in a case in which the controller 56 determines that the fixing force reduction region 19A has been formed in the determination step S30, the process flow may advance to the separation step S50, without undergoing the additional beam application step S40 (that is, NO in S30).

For example, the controller 56 determines that the range of the fixing force reduction region 19A illustrated in FIG. 9 has a sufficient area, and the process flow advances to the separation step S50. In the separation step S50, the base substrate 21 is separated from the device substrate 17 (that is, the support substrate 13).

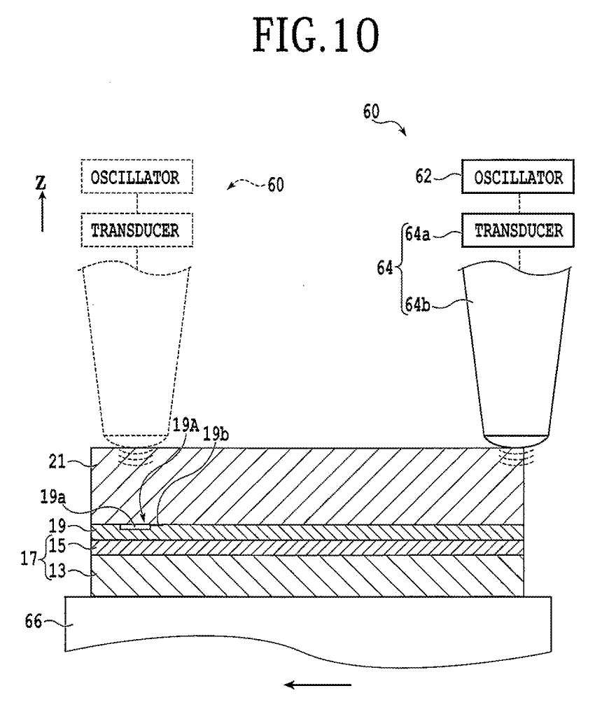

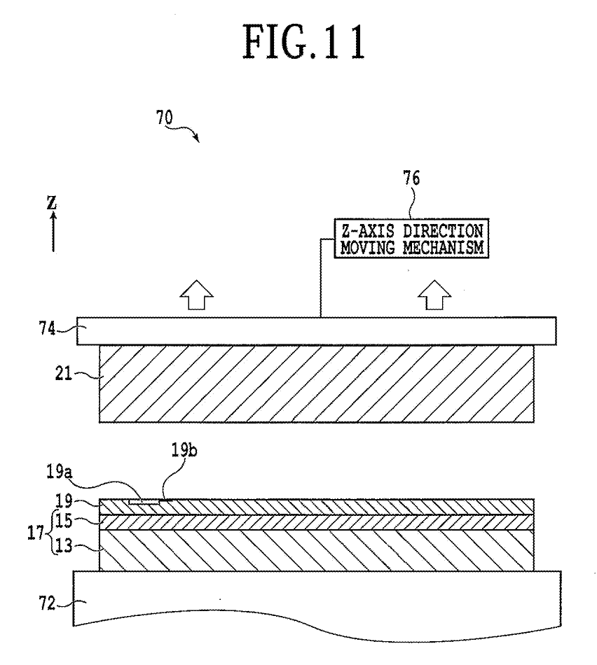

The separation step S50 includes an external force application step (see FIG. 10) of applying ultrasonic vibration (that is, an elastic wave of the frequency of the ultrasonic wave or an external force) to the composite substrate 11, and a peel-off step (see FIG. 11) of physically lifting the base substrate 21 from the device substrate 17 to peel off the base substrate 21 therefrom.

FIG. 10 is a view illustrating the external force application step in the separation step S50. In the external force application step, an ultrasonic wave application apparatus 60 is used. The ultrasonic wave application apparatus 60 includes an oscillator 62 and a vibration unit 64. The oscillator 62 supplies the vibration unit 64 with high-frequency power and controls the frequency of the high-frequency power to a predetermined frequency (for example, resonant frequency).

The vibration unit 64 includes a transducer 64a such as a lead zirconate titanate (PZT) transducer or a bolt-clamped Langevin-type transducer (BLT) and a horn 64b. Power supplied from the oscillator 62 causes the transducer 64a to vibrate at a frequency of the ultrasonic wave (that is, a frequency of 20 kHz or more), and this vibration is transmitted to the composite substrate 11 from a lower end of the horn 64b.

The ultrasonic wave application apparatus 60 includes a chuck table 66 capable of holding under suction the composite substrate 11 as in the chuck table 32. The chuck table 66 is also configured so as to be movable along the X-axis direction and the Y-axis direction by an unillustrated moving mechanism similar to the horizontal moving mechanism 12. In addition, the chuck table 66 is rotatable about a rotational axis parallel to the Z-axis direction by an unillustrated rotational driving mechanism similar to the cylindrical portion 30.

In the external force application step, first, the horn 64b that vibrates at the frequency of the ultrasonic wave is brought into contact with the base substrate 21 immediately above the fixing force reduction region 19A specified in the specification step S20. Then, the ultrasonic vibration (that is, an elastic wave of the frequency of the ultrasonic wave or an external force) is applied to the relevant fixing force reduction region 19A.

Then, with the position of the fixing force reduction region 19A as a start point, the range applied with the ultrasonic vibration is moved to another region, resulting in enlargement of the fixing force reduction region 19A. A relative moving speed of the horn 64b to the chuck table 66 is set to 10 to 100 mm/s (for example, 50 mm/s).

In addition, the frequency of the ultrasonic wave is set to 20 to 100 kHz (for example, 50 kHz), and the output power of the ultrasonic wave is set to 10 to 500 W (for example, 200 W). When viewed in the XY plane perpendicular to the Z-axis direction, the horn 64b may be moved linearly on the composite substrate 11 or may be moved in a spiral shape or any other curved line shape.

Accordingly, compared to a case in which the range applied with the ultrasonic vibration is not moved to another region with the position of the fixing force reduction region 19A as a start point (for example, in a case in which the ultrasonic vibration is applied only to the insufficient region in which the fixing force of the temporary fixing layer 19 is not sufficiently reduced), the range of the fixing force reduction region 19A can be increased easily.

Specifically, compared to a case in which simply such a measure as increasing a period of time for applying the ultrasonic vibration to the composite substrate 11 or further increasing acoustic energy of the ultrasonic wave (W/m²) (that is, increasing an external force to be applied) is taken without taking a measure of specifying the position of the fixing force reduction region 19A, the range of the fixing force reduction region 19A can be increased efficiently, so that reduction in productivity in obtaining the device substrate 17 from the composite substrate 11 can be prevented.

For example, in the region that has already been peeled off (that is the gap 19a) and/or the region that is being peeled off (the modified region 19b), the base substrate 21 is more likely to vibrate than the insufficient region, and accordingly, it is considered that vibrating the fixing force reduction region 19A can gradually enlarge the range in which the fixing force of the temporary fixing layer 19 is reduced.

The movement of the horn 64b according to the present embodiment is automatically performed by a moving mechanism, a rotational mechanism, and the like of the ultrasonic wave application apparatus 60. In this case, the position of the fixing force reduction region 19A serving as the initial position of the horn 64b is input to the ultrasonic wave application apparatus 60, and the horn 64b automatically moves on the composite substrate 11 relatively.

Note that, instead of automatic relative movement of the horn 64b by the ultrasonic wave application apparatus 60, an operator may manually move the horn 64b to the composite substrate 11 held on the chuck table 66. In addition, in place of the horn 64b, water (for example, pure water) applied with the ultrasonic vibration may be jetted to the composite substrate 11 from a nozzle disposed above the composite substrate 11.

After the external force application step is performed, the peel-off step is performed. FIG. 11 is a view illustrating the peel-off step in the separation step S50. In the peel-off step, a peel-off apparatus 70 is used. The peel-off apparatus 70 has a chuck table 72 capable of holding under suction the composite substrate 11 as in the chuck table 32.

Above the chuck table 72, there is provided a disc-shaped suction plate 74 having the substantially same diameter as that of the base substrate 21. The suction plate 74 is movable along the Z-axis direction by a Z-axis direction moving mechanism 76 having a ball screw and the like.

In the peel-off step, in a state in which the support substrate 13 is held under suction on the chuck table 72 and the base substrate 21 is held under suction on the suction plate 74, the suction plate 74 is lifted by the Z-axis direction moving mechanism 76. Accordingly, the base substrate 21 is peeled off from the device substrate 17. In this manner, in the separation step S50 (that is, the external force application step and the peel-off step), with use of the position of the fixing force reduction region 19A, the base substrate 21 is separated.

Note that, in the peel-off step, in place of the peel-off apparatus 70, air is blown to the side surface of the composite substrate 11 held on the chuck table 72, from an unillustrated air jetting apparatus which jets compressed air, and accordingly, the base substrate 21 may be peeled off from the device substrate 17. In place of the air jetting apparatus or along with the air jetting apparatus, an operator may peel off the base substrate 21 manually.

In the peel-off step, for example, although part of the temporary fixing layer 19 remaining after the external force application step but before the peel-off step is left on the device layer 15 (see FIG. 11), the present embodiment is not limited to this, and part of the temporary fixing layer 19 may be left on each of the device layer 15 and the base substrate 21.

Note that the temporary fixing layer 19 remaining on the device layer 15 is selectively removed from the device layer 15 through chemical cleaning. In a case in which the part of the temporary fixing layer 19 is assumed to remain on the device layer 15 in the peel-off step, the peel-off step may include a chemical cleaning step for removing the temporary fixing layer 19 remaining on the device layer 15.

After the separation step S50, with use of a cutting apparatus 80 (see FIG. 12A), the device substrate 17 is divided into a plurality of device chips 33 (dividing step S60). FIG. 12 is a view illustrating the dividing step S60.

As illustrated in FIG. 12A, the cutting apparatus 80 has a disc-shaped chuck table 82 holding under suction the device substrate 17. The chuck table 82 is substantially the same as the chuck table 32 described above, and accordingly, description thereof will be omitted.

The chuck table 82 is rotatable about a rotational axis substantially parallel to the Z-axis direction by a rotational driving mechanism (not illustrated) as in the chuck table 32 described above, and the chuck table 82 and the rotational driving mechanism are supported by an X-axis direction moving mechanism (not illustrated) in such a manner as to be movable to the X-axis direction side.

Above the chuck table 82, there is provided a cutting unit 84. The cutting unit 84 has a cylindrical spindle 86 having a longitudinal portion disposed along the Y-axis direction. The spindle 86 is rotatable at a high speed by a spindle motor (not illustrated). A cutting blade 88 having a cutting edge in an annular shape is attached to a distal end of the spindle 86.

In the dividing step S60, a workpiece unit 31 in which the device substrate 17, a dicing tape 27 made of resin, and a ring frame 29 made of metal are integrated is placed on the chuck table 82. Next, the device substrate 17 is held under suction on a holding surface 82a through the dicing tape 27, and the ring frame 29 is clamped with the clamp mechanisms.

Subsequently, after an inclination of the dividing line 15a (not illustrated in FIGS. 12 and see 1A ) relative to the X-axis direction on the device substrate 17 is specified with use of the microscope camera unit (not illustrated) which is provided above the holding surface 82a, the chuck table 82 is rotated, and an orientation of the chuck table 82 is adjusted in such a manner that the dividing line 15a is substantially parallel to the X-axis direction.

Next, after a lower end of the cutting blade 88 being rotated at a high speed (for example, 25000 rpm) along with the spindle 86 is disposed on an extension line of the dividing line 15a and is also adjusted between the holding surface 82a and the device substrate 17 in the Z-axis direction, the chuck table 82 is moved at a predetermined processing speed (for example, 30 mm/s).

By moving the lower end of the cutting blade 88 and the chuck table 82 along the X-axis direction relative to each other, a cutting groove (in this example, a full-cut groove) is formed from one end to the other end of the dividing line 15a.

After the device substrate 17 is cut along one dividing line 15a, the cutting unit 84 is moved in the Y-axis direction by a predetermined index feed amount, and the lower end of the cutting blade 88 being rotated is disposed on an extension line of another dividing line 15a adjacent in the Y-axis direction to the dividing line 15a along which cutting has been previously performed.

Then, the device substrate 17 is similarly cut along the relevant dividing line 15a. In this manner, the device substrate 17 is cut along all of the dividing lines 15a extending in the X-axis direction, and thereafter, the chuck table 82 is rotated at 90 degrees. Subsequently, in a similar way, the device substrate 17 is cut along all of the dividing lines 15a extending in the Y-axis direction.

In this manner, the device substrate 17 is cut along the plurality of dividing lines 15a disposed in a grid manner and is divided into the plurality of device chips 33. FIG. 12B is a perspective view illustrating one device chip 33.

In the present embodiment, compared to a case in which the range to which the ultrasonic vibration is applied with the position of the fixing force reduction region 19A as a start point is not moved to another region, the range of the fixing force reduction region 19A can be increased easily, so that reduction in productivity in obtaining the device substrate 17 from the composite substrate 11 can be prevented. Hence, reduction in productivity of the device chips 33 can be prevented.

### Modification Example of Dividing Step S60

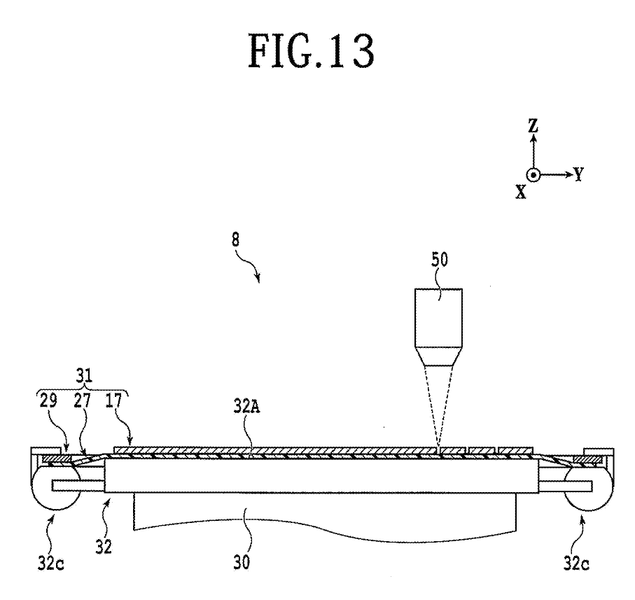

FIG. 13 is a view illustrating a modification example of the dividing step S60. In the modification example, through ablation processing with use of the laser processing apparatus 8 illustrated in FIG. 4, the device substrate 17 is divided into the plurality of device chips 33. Note that, in place of ablation processing, stealth dicing before grinding (SDBG) may cause the device substrate 17 to be divided into the plurality of device chips 33.

### Second Embodiment

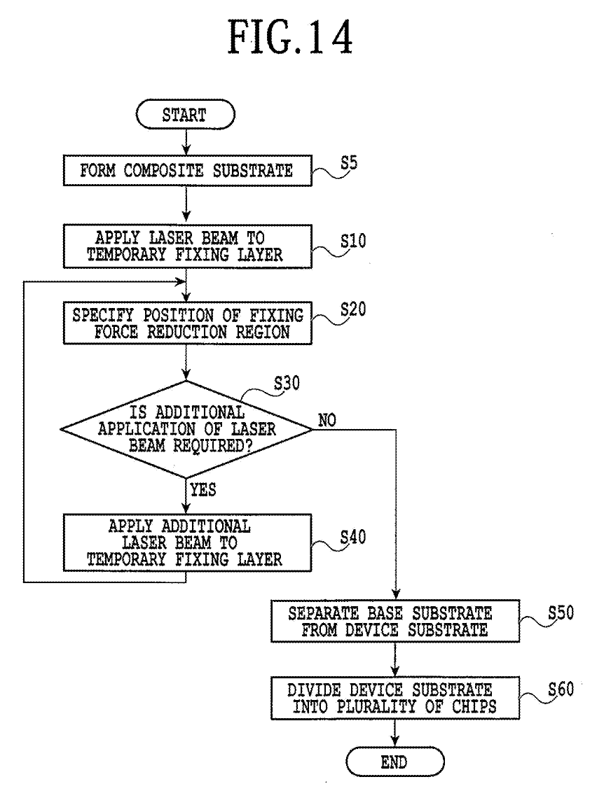

Next, with reference to FIGS. 14-19 , the second embodiment will be described. FIG. 14 is a flowchart indicating a manufacturing method of the device chips 33 according to the second embodiment. In the second embodiment, first, the composite substrate 11 is created (composite substrate forming step S5).

Subsequently, through the fixing force reduction step S10 to the dividing step S50, the device layer 15 is transferred to the support substrate 13 to thereby obtain the device substrate 17, and then, the device substrate 17 is divided into the plurality of device chips 33 in the dividing step S60.

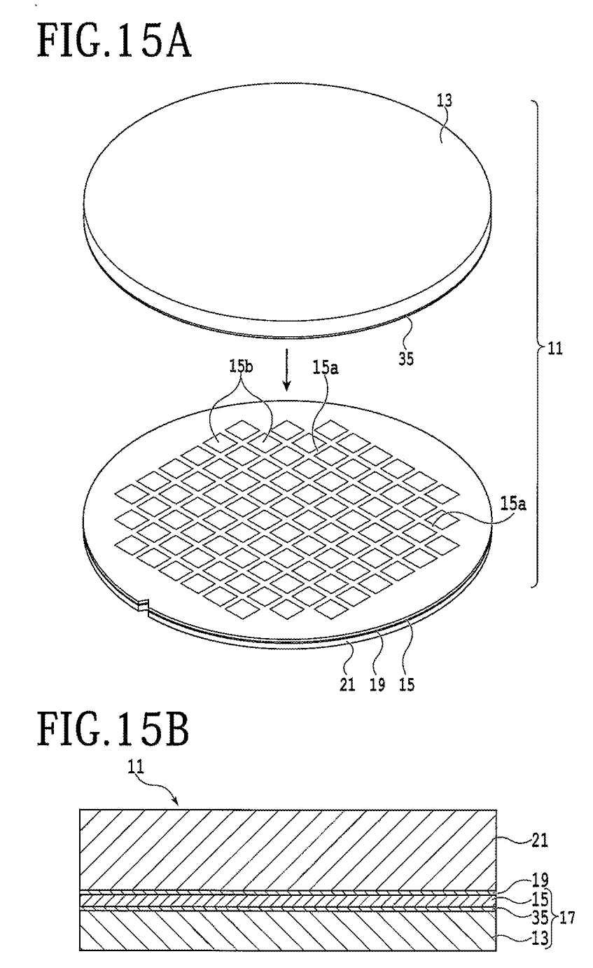

Note that the fixing force reduction step S10 to the dividing step S60 are the same as those in the first embodiment, and the second embodiment is different from the first embodiment in the composite substrate forming step S5. FIG. 15A is a view illustrating the composite substrate forming step S5. When the composite substrate 11 is to be formed, first, the temporary fixing layer 19 and the device layer 15 are successively formed on the base substrate 21.

Next, after a fixing layer 35 made of metal is formed on a back surface of the support substrate 13 by deposition, the device layer 15 formed over the base substrate 21 and the fixing layer 35 formed on the support substrate 13 are pressure-bonded to each other in a state that the device layer 15 and the fixing layer 35 are in contact with each other. Note that, upon press bonding, one of or both the support substrate 13 and the base substrate 21 may be heated.

Accordingly, the composite substrate 11 is formed. FIG. 15B is a cross-sectional view illustrating the composite substrate 11 created in the composite substrate forming step S5. Note that the composite substrate 11 illustrated in FIG. 15B and the composite substrate 11 illustrated in FIG. 15A are upside down.

One surface of the fixing layer 35 is in contact with the device layer 15, and the other surface of the fixing layer 35 is in contact with the support substrate 13. The fixing layer 35 is made of, for example, a gold-tin alloy, gold, platinum, chromium, indium, or palladium. The thickness of the temporary fixing layer 19 is, for example, 1 to 10 µm (typically, 3 µm).

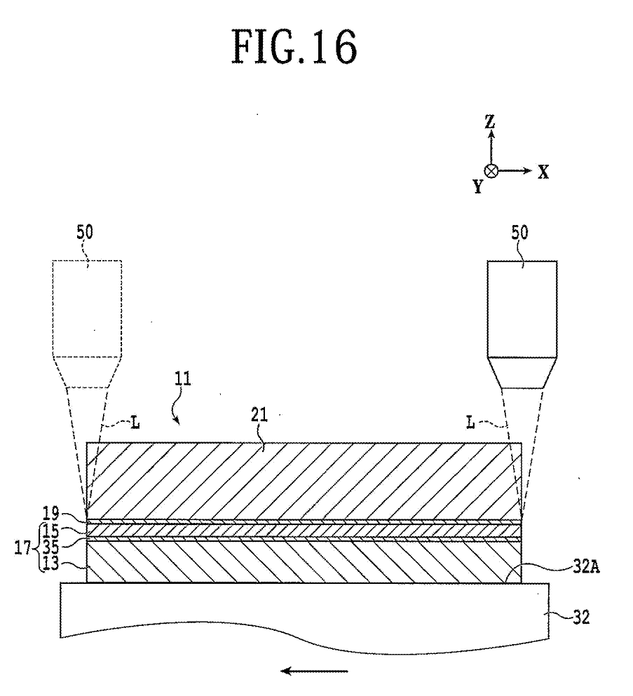

FIG. 16 is a view illustrating the fixing force reduction step S10 according to the second embodiment. The fixing force reduction step S10 is the same as the fixing force reduction step S10 illustrated in FIG. 5, and accordingly, detailed description thereof will be omitted.

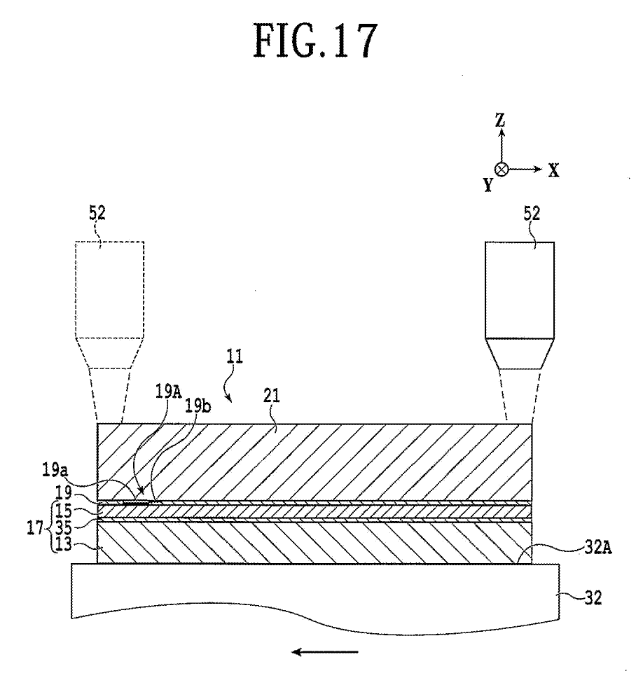

FIG. 17 is a view illustrating the specification step S20 according to the second embodiment. The specification step S20 is the same as the specification step S20 illustrated in FIG. 6, and accordingly, detailed description will be omitted. After the specification step S20, the process flow advances to the separation step S50 through the determination step S30 and the additional beam application step S40.

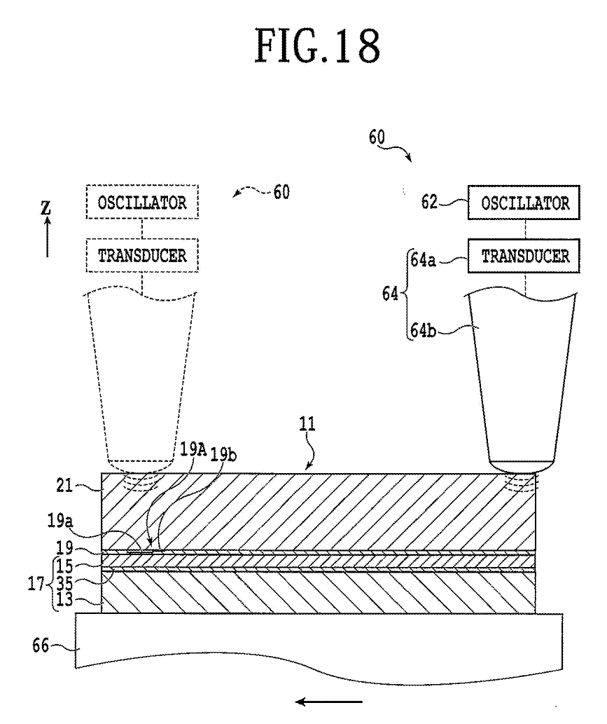

FIG. 18 is a view illustrating an external force application step in the separation step S50 according to the second embodiment. The external force application step is the same as the external force application step illustrated in FIG. 10, and accordingly, detailed description will be omitted. After the external force application step is performed, the process flow advances to a peel-off step.

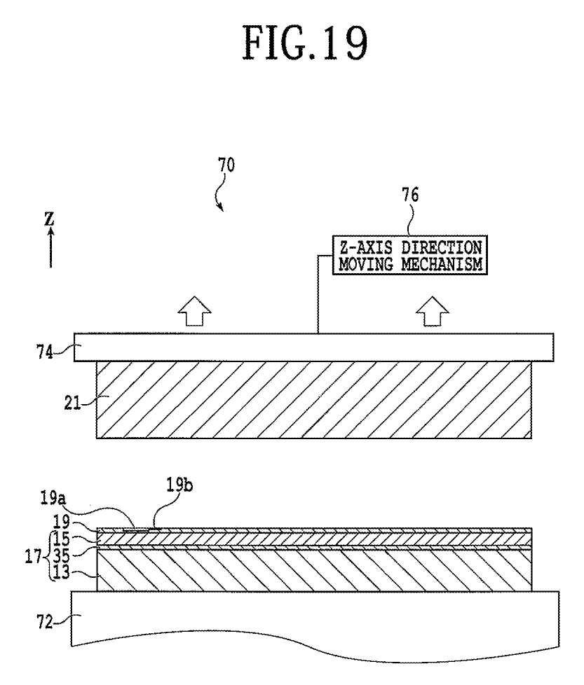

FIG. 19 is a view illustrating the peel-off step in the dividing step S50 according to the second embodiment. The peel-off step is the same as the peel-off step illustrated in FIG. 11, and accordingly, detailed description will be omitted. After the peel-off step is performed, the process flow advances to the dividing step S60. The dividing step S60 is the same as the dividing step S60 illustrated in FIG. 12A, and accordingly, detailed description will be omitted.

Also in the second embodiment, reduction in productivity in obtaining the device substrate 17 from the composite substrate 11 can be prevented. Hence, reduction in productivity of the device chips 33 can be prevented.

Other structures, methods, and the like according to the present embodiments above can be implemented with appropriate modifications within a range not departing from the scope of the object of the present invention. In the embodiments described above, an example in which the device layer 15 is provided between the support substrate 13 and the temporary fixing layer 19 is given, but the device layer 15 may not necessarily be required. The device layer 15 may not be provided in the composite substrate 11.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A substrate manufacturing method for obtaining, from a composite substrate in which a first substrate, a temporary fixing layer, and a second substrate are stacked in this order, the first substrate from which the second substrate has been separated, the method comprising:
applying a laser beam having a wavelength absorbable by the temporary fixing layer, to the temporary fixing layer;
after the laser beam is applied to the temporary fixing layer, specifying a position of a fixing force reduction region in which a fixing force between the first substrate and the second substrate in the temporary fixing layer is reduced; and
separating the second substrate from the first substrate using the specified position of the fixing force reduction region.

2. The substrate manufacturing method according to claim 1,
wherein, in the separating of the second substrate from the first substrate, an external force is applied to the fixing force reduction region.

3. The substrate manufacturing method according to claim 1,
wherein, in the specifying of the position of the fixing force reduction region, the position of the fixing force reduction region is specified based on an image obtained by imaging the composite substrate.

4. The substrate manufacturing method according to claim 1, further comprising:
after the position of the fixing force reduction region is specified, applying the laser beam to a region of the temporary fixing layer in which the fixing force is not sufficiently reduced, to reduce the fixing force of the temporary fixing layer.

5. The substrate manufacturing method according to claim 2, further comprising:
after the position of the fixing force reduction region is specified, applying the laser beam to a region of the temporary fixing layer in which the fixing force is not sufficiently reduced, to reduce the fixing force of the temporary fixing layer.

6. The substrate manufacturing method according to claim 3, further comprising:
after the position of the fixing force reduction region is specified, applying the laser beam to a region of the temporary fixing layer in which the fixing force is not sufficiently reduced, to reduce the fixing force of the temporary fixing layer.

7. The substrate manufacturing method according to claim 1,
wherein the fixing force reduction region is a region in which modification has relatively progressed in the temporary fixing layer that has been irradiated with the laser beam.

8. The substrate manufacturing method according to claim 7,
wherein the fixing force reduction region is a region in which the first substrate and the second substrate are spatially separated from each other or a region in which a color of an interface between the second substrate and the temporary fixing layer is changed compared to a color of the temporary fixing layer before the application of the laser beam.

9. A chip manufacturing method of manufacturing a plurality of chips by dividing a first substrate after separating a second substrate from a composite substrate having the first substrate, a temporary fixing layer, and the second substrate stacked in this order, the method comprising:
applying a laser beam having a wavelength absorbable by the temporary fixing layer, to the temporary fixing layer;
after the laser beam is applied to the temporary fixing layer, specifying a position of a fixing force reduction region in which a fixing force between the first substrate and the second substrate in the temporary fixing layer is reduced;
separating the second substrate from the first substrate, with use of the specified position of the fixing force reduction region; and
after separating the second substrate from the first substrate, dividing the first substrate into the plurality of chips.

10. A processing apparatus for reducing a fixing force of a temporary fixing layer in a composite substrate having a first substrate, the temporary fixing layer, and a second substrate stacked in this order, the processing apparatus comprising:
a laser beam applying unit that applies a laser beam having a wavelength absorbable by the temporary fixing layer, to the temporary fixing layer; and
a fixing force reduction region specifying unit that specifies a position of a fixing force reduction region in which a fixing force between the first substrate and the second substrate is reduced in the composite substrate in which the temporary fixing layer is irradiated with the laser beam.
